(19) United States
(12) Patent Application Publication
(10) Pub. No.: US 2011/0133291 A1
(43) Pub. Date: Jun. 9, 2011

(54) SEMICONDUCTOR DEVICE AND METHOD OF FABRICATING SAME

(75) Inventor: Mayumi Shibata, Miyagi (JP)

(73) Assignee: OKI SEMICONDUCTOR CO., LTD., Tokyo (JP)

(21) Appl. No.: 12/915,084

(22) Filed: Oct. 29, 2010

(30) Foreign Application Priority Data
Dec. 8, 2009 (JP) 2009-278559

(51) Int. Cl. H01L 27/088; H01L 21/336

(52) U.S. Cl. 257/392; 438/294; 257/E27.06; 257/E21.409

(57) ABSTRACT

Disclosed is a fabrication method which includes: forming a first gate electrode and a second gate electrode which cross over an active region, the overall width of the second gate electrode being less than that of the first gate electrode; ion-implanting dopants into the active region at an oblique angle using the first and second gate electrodes as a mask for ion-implantation, thereby to form separated doped regions on opposite sides of the first gate electrode and to form a continuous doped region extending from one of opposite sides of the second gate electrode to the other.

### BACKGROUND OF THE INVENTION

1. Field of the Invention

The present invention relates to a semiconductor device that includes both an enhancement-mode FET (enhancement-mode Field Effect Transistor) and a depletion-mode FET (depletion-mode Field Effect Transistor), and to techniques for fabricating the same.

2. Description of the Related Art

Field effect transistors (FETs) such as MOSFETs (Metal-Oxide-Semiconductor Field-Effect Transistors) have been widely used for semiconductor integrated circuits such as drive circuits of liquid crystal displays, and decode circuits of RAMS (Random Access Memories) or ROMs (Read Only Memories). One of such semiconductor integrated circuits is an integrated circuit in which two types of FETs, enhancement-mode FETs and depletion-mode FETs, are integrated on a semiconductor substrate. For example, Japanese Patent Application Publication No. H11-174405 discloses a drive circuit of a liquid crystal display in which enhancement-mode FETs and depletion-mode FETs are integrated.

The problem with the integration of different types of FETs (i.e., enhancement-mode FETs and depletion-mode FETs) on the semiconductor substrate is that the fabrication process including the integration of different types of FETs becomes more complicated compared with that including integration of the same type of FETs, resulting in relatively high cost. An example of such a problem will be described with reference to FIGS. 1A, 1B, and 2. FIG. 1A is a schematic top view of a semiconductor structure for producing enhancement-mode and depletion-mode FETs using a conventional fabrication process, and FIG. 1B is a cross-sectional view taken along line Ib-Ib of FIG. 1A. Also, FIG. 1A schematically illustrates gate electrodes 101A, 101B, 101C, and 101D formed on an active region 102. FIG. 2 is a cross-sectional view of a semiconductor structure for describing a part of the conventional fabrication process of a depletion-mode FET. Referring to FIGS. 1A and 1B, an active region 102 is surrounded by isolation structures 105A and 105B. An insulating film 104 for forming a gate-insulating film by a post-process is formed on a semiconductor substrate 100. Gate electrodes 101A, 101C, 101D for enhancement-mode FETs and a gate electrode 101B for a depletion-mode FET are formed on the insulating film 104.

An area 103 illustrated in FIG. 1A is an area in which the depletion-mode FET is to be formed. As illustrated in FIG. 2, a photoresist pattern 106 is formed over the semiconductor structure of FIGS. 1A and 1B by a photolithography process. The photoresist pattern 106 covers the gate electrodes 101A, 101C and 101D for enhancement-mode FETs, and has a patterned opening in which the gate electrode 101B is placed. A doped region (impurity-doped region) 110 is further formed below the gate electrode 101B by ion-implanting dopant impurities into the semiconductor substrate 100 through the insulating film 104 using the photoresist pattern 106 as a mask for ion-implantation. The doped region 110 is to control the threshold voltage of a depletion-mode FET. P-type dopants such as Boron (B) for a p-channel FET or n-type dopants such as Arsenic (As) for an n-channel FET can be ion-implanted as the dopant impurities. After the ion-implantation, the photoresist pattern 106 is removed. Then, doped regions (not shown) for LDD (Lightly Doped Drain) regions are formed on opposite sides of each of the gate electrodes 101A, 101C and 101D for enhancement-mode FETs by ion-implanting dopant impurities into the semiconductor substrate 100.

The problem with the above fabrication process is that the photolithography process and the ion-implantation are needed only to form the doped region 110 for a depletion-mode FET below the gate electrode 101B, resulting in high cost.

In view of the foregoing, it is an object of the present invention to provide a method capable of reducing the total number of steps of the fabrication process of a semiconductor device in which enhancement-mode and depletion-mode FETs are integrated on a semiconductor substrate. It is another object of the present invention to provide the semiconductor device fabricated using the method.

### SUMMARY OF THE INVENTION

According to an aspect of the invention, a method of fabricating a semiconductor device in which enhancement-mode and depletion-mode FETs are integrated on a semiconductor substrate is provided. The method includes: forming an active region surrounded by an isolation structure in the semiconductor substrate; forming a first gate electrode and a second gate electrode over a main surface of the semiconductor substrate, the first gate electrode crossing over the active region in a width direction of the active region, and the second gate electrode crossing over the active region in the width direction and having an overall width along the width direction which is less than an overall width of the first gate electrode; ion-implanting dopants into the active region at an oblique angle of incidence relative to a normal line perpendicular to the main surface of the semiconductor substrate, using the first and second gate electrodes as a mask for implantation, thereby to form a first doped region, a second doped region and a third doped region, the first and second doped regions being formed in the active region on opposite sides of the first gate electrode aligned along a gate-length direction of the first gate electrode and being separated from each other, and the third doped region being continuously formed in the active region so as to extend from one of opposite sides of the second gate electrode to the other along a gate-length direction of the second gate electrode; forming a first source region and a first drain region in the active region on the opposite sides of the first gate electrode; and forming a second source region and a second drain region in the active region on the opposite sides of the second gate electrode.

According to another aspect of the invention, a semiconductor device is provided. The semiconductor device includes a semiconductor substrate in which an isolation structure is formed; an active region surrounded by the isolation structure in the semiconductor substrate; and enhancement-mode and depletion-mode FETs formed in and on the active region. The enhancement-mode FET includes a first gate electrode formed over a main surface of the semiconductor substrate and crossing over the active region in a width direction of the active region; first and second doped regions separated from each other, the first and second doped regions being formed below the first gate electrode and formed in the active region on opposite sides of the first gate electrode aligned along a gate-length direction of the first gate electrode; and a first source region and a first drain region formed in the active region on the opposite sides of the first gate electrode. The depletion-mode FET includes a second gate electrode formed over the main surface and crossing over the active region in a width direction of the active region, the second gate electrode having an overall width along the width direction which is less than an overall width of the first gate electrode; a third doped region formed below the second gate electrode and continuously formed in the active region so as to extend from one of opposite sides of the second gate electrode to the other along a gate-length direction of the second gate electrode; and a second source region and a second drain region formed in the active region on the opposite sides of the second gate electrode.

According to the invention, the first and second doped regions for the enhancement-mode FET and the third doped region for the depletion-mode FET can be formed in the same process. This enables reduction of the total number of fabrication steps and lower fabrication cost.

### BRIEF DESCRIPTION OF THE DRAWINGS

In the attached drawings:

FIG. 1A is a schematic top view of a semiconductor structure for fabricating enhancement-mode and depletion-mode FETs using a conventional fabrication process;

FIG. 1B is a cross-sectional view taken along line Ib-Ib of FIG. 1A;

FIG. 2 is a cross-sectional view of a semiconductor structure for describing a part of the conventional fabrication process of a depletion-mode FET;

FIG. 3A is a schematic top view of a semiconductor structure for fabricating enhancement-mode and depletion-mode FETs using a fabrication method of an embodiment of the present invention;

FIG. 3B is a cross-sectional view taken along line IIIb-IIIb of FIG. 3A;

FIG. 4A is a schematic top view of a semiconductor structure for fabricating enhancement-mode and depletion-mode FETs using a fabrication method of the embodiment;

FIG. 4B is a cross-sectional view taken along line IVb-IVb of FIG. 4A;

FIG. 5A is a cross-sectional view taken along line Va-Va of FIG. 4A;

FIG. 5B is a cross-sectional view taken along line Vb-Vb of FIG. 4A;

FIG. 6 is a schematic cross-sectional view of enhancement-mode and depletion-mode FETs fabricated using the fabrication method of the embodiment; and

FIGS. 7A and 7B illustrate the characteristics of drain current versus gate voltage for both an enhancement-mode MOSFET and a depletion-mode MOSFET.

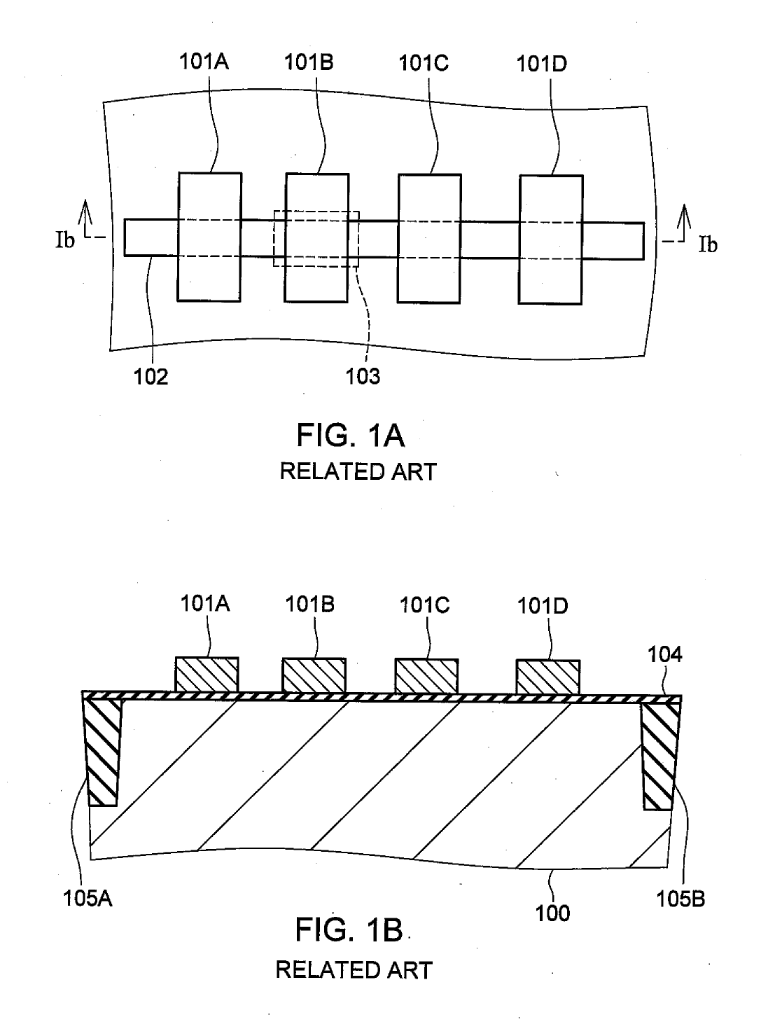

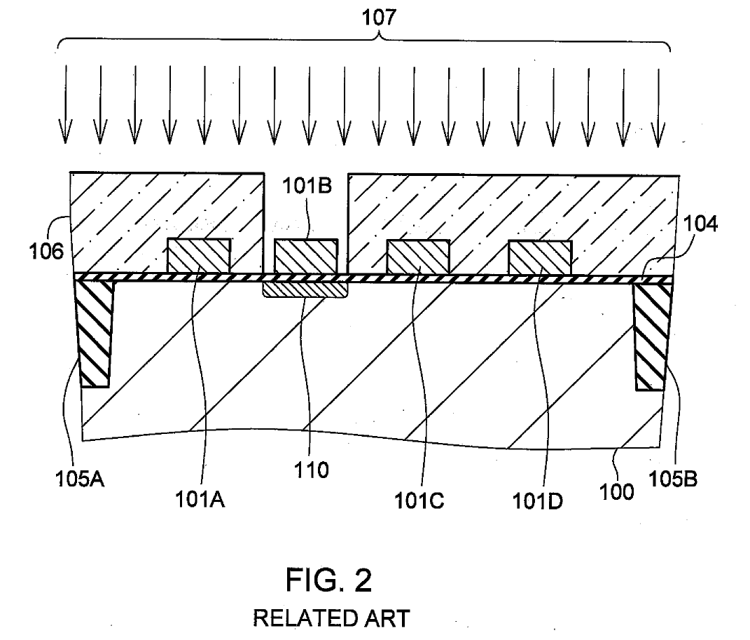

### DETAILED DESCRIPTION OF THE INVENTION

Embodiments of the invention will now be described with reference to the attached drawings, in which like elements are indicated by like reference characters.

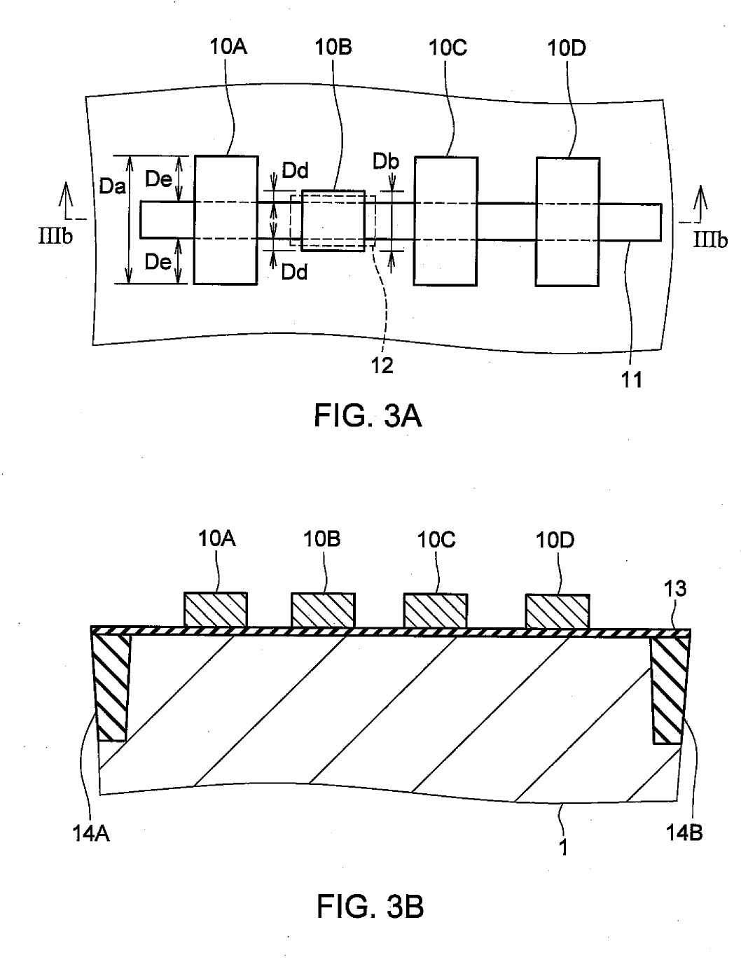

FIGS. 3A, 3B, 4A, 4B, 5A, 5B and 6 are schematic views of semiconductor structures for describing a main part of a fabrication method of the embodiment. The fabrication method will be described with reference to FIGS. 3A, 3B, 4A, 4B, 5A, 5B and 6. FIG. 3A is a schematic top view of a semiconductor structure in which gate electrodes 10A, 10B, 10C and 10D are formed over an active region 11. FIG. 3B is a cross-sectional view taken along line IIIb-IIIb of FIG. 3A. An area 12 illustrated in FIG. 3A is an area in which a depletion-mode FET is to be formed.

In the fabrication method of the embodiment, a semiconductor substrate 1 is first prepared. An n-type silicon substrate or a semiconductor substrate having an n-well structure can be prepared for fabrication of a p-channel MOSFET. Alternatively, a p-type silicon substrate or a semiconductor substrate having a p-well structure can be prepared for fabrication of an n-channel MOSFET. Next, isolation structures including dielectric insulating materials are formed in the semiconductor substrate 1 by a LOCOS (LOCal Oxidation of Silicon) isolation process or an STI (Shallow Trench Isolation) process as is well known in the art. Contaminants are then removed from the surface of the semiconductor substrate 1 by a cleaning process. An insulating film 13 (illustrated in FIG. 3B) is formed on the surface (a main surface) of the semiconductor substrate 1 by thermal oxidation. As a result, the active region 11 surrounded by the isolation structures is formed as illustrated in FIG. 3A. In the top view of FIG. 3A, the insulating film 13 is not shown for the sake of convenience.

After the formation of the insulating film 13, patterned gate electrodes 10A, 10B, 10C and 10D are formed over the main surface of the semiconductor substrate 1 by photolithography and etching processes. Each of the gate electrodes 10A, 10B, 10C and 10D can have a structure including, for example, a polycrystalline silicon film that is highly doped with n-type dopants. Gate electrodes 10A, 10B, 10C and 10D are regularly arranged in the area between the isolation structures 14A and 14B as illustrated in FIG. 3B, and formed crossing over the active region 11 along the width direction of the active region 11 as illustrated in FIG. 3A.

The gate electrode 10B for a depletion-mode FET has an overall width Db that is defined as the distance between the opposite edges of the gate electrode 10B aligned along the gate-width direction of the gate electrode 102 (parallel to the width direction of the active region 11). Each of the gate electrodes 10A, 10C and 10D for enhancement-mode FETs also have an overall width Da that is defined as the distance between the opposite edges of each gate electrode aligned along their gate-width direction. The overall width Db of the gate electrode 10B is less than the overall width Da of the gate electrodes 10A, 10C and 10D. Further, each of the gate electrodes 10A, 10C and 10D have protrusions with a protrusion length De which protrude outwardly at opposite side edges of the active region 11 aligned along the width direction. The gate electrode 10B also has protrusions with a protrusion length Dd that protrude outwardly at opposite side edges of the active region 11 aligned along the width direction. The protrusion length is defined as the distance from the base to the tip of the protrusion. The protrusion length De is larger than the protrusion length Dd.

In the embodiment, the protrusion length De is preferably set to be larger than or equal to 0.3 micrometers and the protrusion length Dd is preferably set to be in the range from 0.1 micrometers to 0.2 micrometers, in order to fabricate enhancement-mode and depletion-mode FETs as will be explained more in detail below.

After the formation of the gate electrodes 10A to 10D, dopant impurities are ion-implanted into the active region 11 at an oblique angle relative to the normal line perpendicular to the main surface of the semiconductor substrate 1, using the gate electrodes 10A to 10D as a mask for ion-implantation. For the fabrication of a p-channel MOSFET, for example, boron ions can be implanted at accelerating voltages ranging from 60 keV to 150 keV with doses ranging from 1.0×10¹³ ions/cm² to 1.0×10¹⁴ ions/cm². For the fabrication of an n-channel MOSFET, n-type dopants such as phosphor can be ion-implanted at an oblique angle. Further, in connection with the protrusion lengths De and Dd described above, the dopant impurities are preferably ion-implanted into the active region 11 at oblique angles ranging from 30 to 60 degrees, more preferably at about 45 degree, relative to the normal line. During the oblique-angle ion-implantation, the dopant impurities can be ion-implanted at an oblique angle by rotating the semiconductor substrate 1 around its central axis tilted to the direction of an incident ion beam. The angular distribution of the incident ion beams onto the semiconductor substrate 1 is symmetric around the central axis.

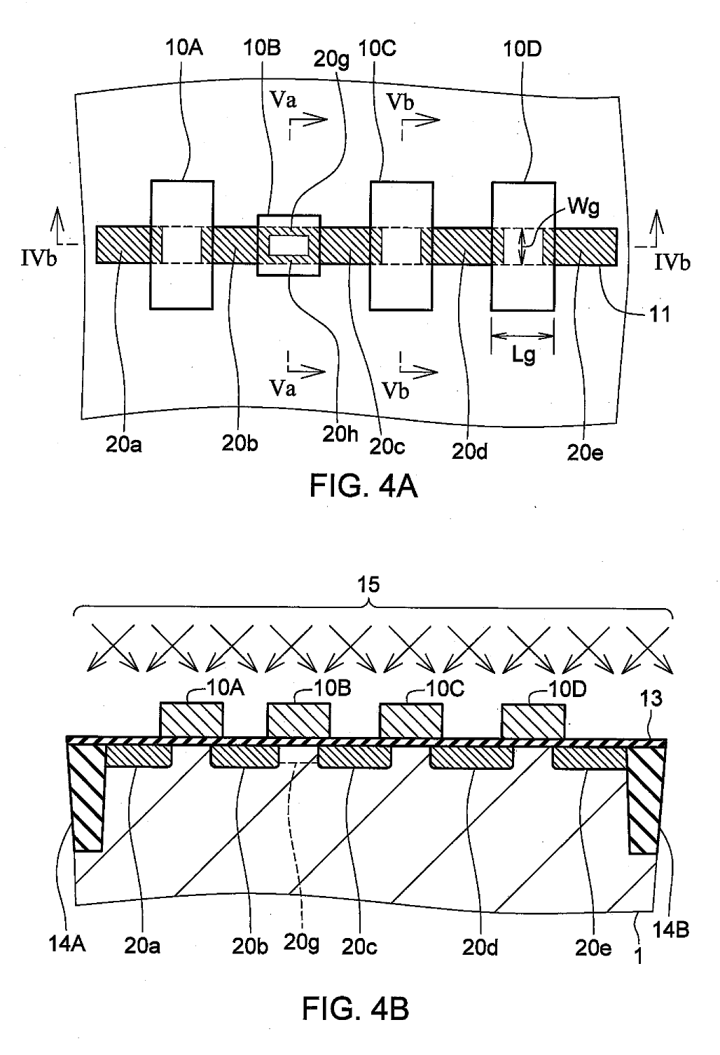

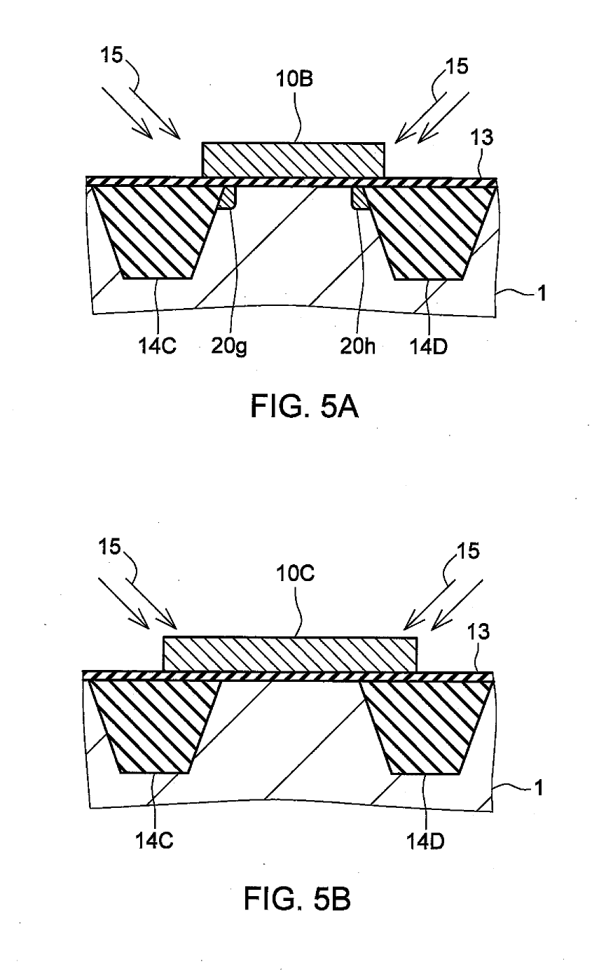

FIG. 4A is a schematic top view of the semiconductor structure in which gate electrodes 10A to 10D are formed on the active region 11 that is doped by the oblique angle ion-implantation. FIG. 4B is a cross-sectional view taken along line IVb-IVb of FIG. 4A. FIG. 5A is a cross-sectional view taken along line Va-Va of FIG. 4A, and FIG. 5B is a cross-sectional view taken along line Vb-Vb of FIG. 4A.

As illustrated in FIG. 4B, doped regions 20a, 20b, 20c, 20d, and 20e are formed by ion-implanting dopant impurities 15 at oblique angles in a plane parallel to the longitudinal direction of the active region 11 (i.e., the gate-length direction of the gate electrodes 10A to 10D) and substantially perpendicular to the main surface of the semiconductor substrate 1, using the gate electrodes 10A to 10D as a mask for ion-implantation. These doped regions 20a to 20e will be activated by post thermal treatment to form LDD (Lightly Doped Drain) regions or extension regions.

As illustrated in FIG. 5A, doped regions 20g and 20h are formed by ion-implanting dopant impurities 15 at oblique angles in a plane parallel to the width direction of the active region 11, using the gate electrode 10B for a depletion-mode MOSFET as a mask for ion-implantation. These doped regions 20g and 20h are located in the vicinities of the opposite side edges of the active region 11 aligned along the width direction (i.e., in the vicinities of isolation structures 14C and 14D of FIG. 5A).

On the other hand, as illustrated in FIG. 5B, the oblique angle ion-implantation using the gate electrode 10C for an enhancement-mode MOSFET as a mask does not allow the formation of doped regions in the vicinities of the opposite side edges of the active region 11. This is because the protrusion length De (illustrated in FIG. 3A) of the gate electrode 10C is large, and both end portions of the gate electrode 10C shield against incoming dopants ion-implanted at the oblique angle. The incoming dopants cannot reach the active region 11. Other gate electrodes 10A and 10D also shield against the incoming dopants in the same way.

As a result of the oblique angle ion-implantation described above, as illustrated in the top view of FIG. 4A, the doped regions 20a and 20b which are spatially separated from each other are formed on opposite sides of the gate electrode 10A aligned along the gate-length direction of the gate electrode 10A. The doped regions 20c and 20d which are spatially separated from each other are formed on opposite sides of the gate electrode 10C aligned along the gate-length direction of the gate electrode 10C. The doped regions 20d and 20e which are spatially separated from each other are formed on opposite sides of the gate electrode 10D aligned along the gate-length direction of the gate electrode 10D. In contrast, the doped regions 20g and 20h are continuously formed directly below the gate electrode 10B for a depletion-mode MOSFET. These doped regions 20g and 20h extend in the active region 11 from one of the opposite sides of the gate electrode 10B to the other along the gate-length direction of the gate electrode 10B. These doped regions 20g and 20h will be activated by post thermal treatment to form their respective conductive layers for controlling the threshold voltage of the depletion-mode MOSFET.

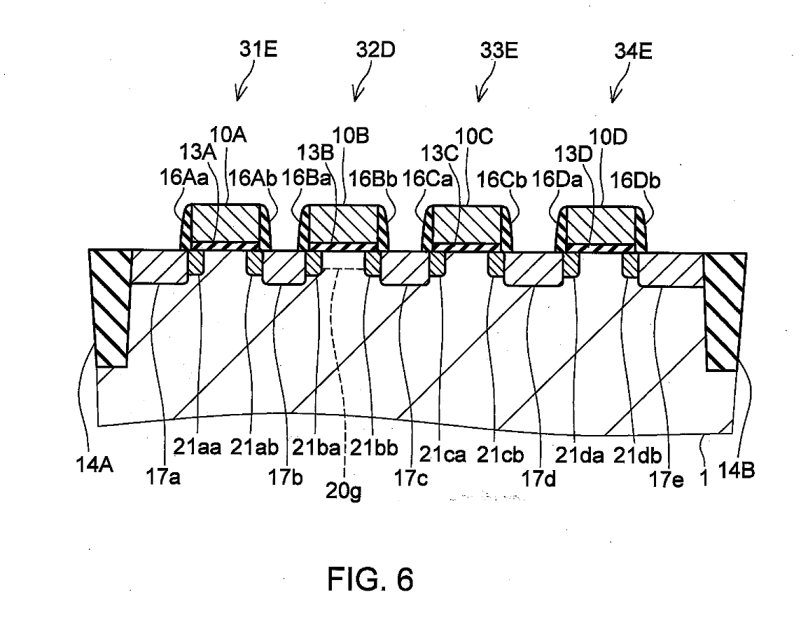

Thereafter, an insulating dielectric material such as silicon nitride (SiNx) or non-doped silicate glass (NSG) is deposited on the semiconductor structure illustrated in FIGS. 4A and 4B by CVD (Chemical Vapor Deposition), and etched back by anisotropic etching. As a result, sidewall spacers 16Aa, 16Ab, 16Ba, 16Bb, 16Ca, 16Cb, 16Da and 16Db as illustrated in FIG. 6 are formed on the sidewalls of the gate electrodes 10A to 10D. At a sufficiently high concentration, dopants are then introduced in the active region 11 on the opposite sides of each of the gate electrodes 10A to 10D, using the sidewall spacers 16Aa, 16Ab, 16Ba, 16Bb, 16Ca, 16Cb, 16Da and 16Db and the isolation structures as a mask. The introduced dopants are activated by thermal treatment such as RTA (Rapid Thermal Annealing).

Consequently, as illustrated in FIG. 6, source/drain regions 17a and 17b on the opposite sides of the gate electrode 10A, source/drain regions 17b and 17c on the opposite sides of the gate electrode 10B, source/drain regions 17c and 17d on the opposite sides of the gate electrode 10C, and source/drain regions 17d and 17e on the opposite sides of the gate electrode 10D are formed in the active region 11 with a self-aligning process. Also, a pair of opposite LDD regions or extension regions 21aa and 21ab is formed below the gate electrode 10A, extending laterally from the source/drain regions 17a and 17b toward each other. A pair of opposite LDD regions or extension regions 21ba and 21bb is formed below the gate electrode 10B, extending laterally from the source/drain regions 17b and 17c toward each other. A pair of opposite LDD regions or extension regions 21ca and 21cb is formed below the gate electrode 10C, extending laterally from the source/drain regions 17c and 17d toward each other. A pair of opposite LDD regions or extension regions 21da and 21db is formed below the gate electrode 10D, extending laterally from the source/drain regions 17d and 17e toward each other. Moreover, the doped regions 20g and 20h below the gate electrode 10B are activated by the above thermal treatment to form their respective conductive layers. In FIG. 6, the conductive layer 21g formed by the activation of the doped regions 20g is illustrated.

By the above-described main part of the fabrication method, enhancement-mode MOSFETs 31E, 33E and 34E and a depletion-mode MOSFET 32D are fabricated in and on the semiconductor substrate 1. Further, an interconnect structure (now shown) is formed over the MOSFETs 31E to 34E of FIG. 6 by processes including deposition of interlayer dielectric films, formation of contact holes, and formation of interconnect layers, and, finally, a semiconductor device according to the present embodiment is fabricated.

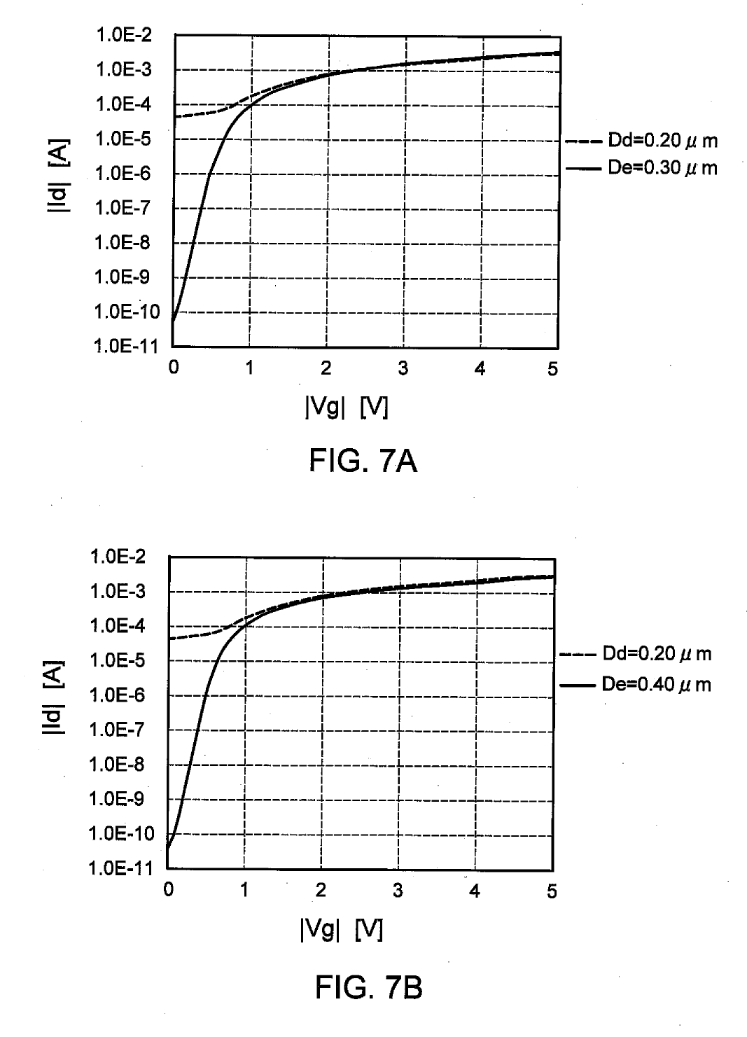

FIGS. 7A and 7B illustrate the characteristics of drain current versus gate voltage for both an enhancement-mode MOSFET and a depletion-mode MOSFET, where the horizontal axis represents the range of the absolute values |Vg| of the gate-source voltages Vg (measured in volts), and the vertical axis represents, with values ranging from 1.0×10⁻¹¹ (1.0E-11) to 1.0×10⁻² (1.0E-2), the range of the absolute values |Id| of the drain currents Id (measured in amperes). The enhancement-mode MOSFET and the depletion-mode MOSFET which were tested have the same structure except that their protrusion lengths De and Dd are different from each other. Namely, each of the MOSFETs tested has a gate-length of Lg=1.0 micrometers, and a gate-width of Wg=0.6 micrometers. In the oblique angle ion-implantation, boron ions (its atomic mass number is 11) with an oblique angle of incidence of 45 degrees are implanted at an accelerating voltage of 80 keV with a dose of 2.0×10¹³ ions/cm². In the graph of FIG. 7A, a characteristic curve (solid line) for the enhancement-mode MOSFET with a protrusion length De of about 0.30 micrometers, and a characteristic curve (dashed line) for the depletion-mode MOSFET with a protrusion length Dd of about 0.20 micrometers are illustrated. In the graph of FIG. 7B, a characteristic curve (solid line) for the enhancement-mode MOSFET with a protrusion length De of about 0.40 micrometers, and a characteristic curve (dashed line) for the depletion-mode MOSFET with a protrusion length Dd of about 0.20 micrometers are illustrated.

According to the graphs of FIGS. 7A and 7B, a desired characteristic of the enhancement-mode MOSFET can be obtained for the protrusion length of De=0.30 micrometers or more. A desired characteristic of the depletion-mode MOSFET also can be obtained for the protrusion length of Dd=0.20 micrometers or less.

As described above, in the fabrication method of the embodiment, the overall width Db of the gate electrode 10B for a depletion-mode FET is less than the overall width Da of the gate electrodes 10A, 10C and 10D for enhancement-mode FETs so that the protrusion length Dd of the gate electrode 10B is less than the protrusion length De of the gate electrodes 10A, 10C and 10D. Dopant impurities are then ion-implanted into the active region 11 at oblique angles, thereby forming, below the gate electrode 10B, the doped regions 20g and 20h for controlling the threshold voltage of a depletion-mode FET. Since the doped regions 20g and 20h for the depletion-mode FET and the doped regions 20a to 20e for enhancement-mode FETs can be simultaneously formed by the same process, a photolithography process and an ion-implantation to separately form the doped regions 20g and 20h are not needed. This enables reduction of the total number of fabrication steps and lower fabrication cost compared with conventional fabrication processes.

Additionally, since the protrusion length De of the gate electrodes 10A, 10C and 10D can be set to be 0.30 micrometers or more, it is possible to obtain a desired characteristic of the enhancement-mode MOSFET. Since the protrusion length Dd of the gate electrode 10B can be set to be 0.20 micrometers or less, it is possible to obtain a desired characteristic of the depletion-mode MOSFET.

The invention is not limited to the embodiment described above and shown in the drawings. For example, the semiconductor device of the above embodiment preferably has the structure in which the depletion-mode FET 32D and the enhancement-mode FETs 31E, 33E and 34E are formed in and on the single active region 11, no limitation thereto intended. The embodiment can be modified to form the depletion-mode FET and the enhancement-mode FETs in and on different active regions, respectively.

Those skilled in the art will recognize that further variations are possible within the scope of the invention, which is defined in the appended claims.

What is claimed is:

1. A method of fabricating a semiconductor device in which enhancement-mode and depletion-mode FETs are integrated on a semiconductor substrate, said method comprising:
forming an active region surrounded by an isolation structure in said semiconductor substrate;
forming a first gate electrode and a second gate electrode over a main surface of said semiconductor substrate, said first gate electrode crossing over said active region in a width direction of said active region, and said second gate electrode crossing over said active region in the width direction and having an overall width along the width direction which is less than an overall width of said first gate electrode;
ion-implanting dopants into said active region at an oblique angle of incidence relative to a normal line perpendicular to said main surface of said semiconductor substrate, using said first and second gate electrodes as a mask for implantation, thereby to form a first doped region, a second doped region and a third doped region, said first and second doped regions being formed in said active region on opposite sides of said first gate electrode aligned along a gate-length direction of said first gate electrode and being separated from each other, and said third doped region being continuously formed in said active region so as to extend from one of opposite sides of said second gate electrode to the other along a gate-length direction of said second gate electrode;
forming a first source region and a first drain region in said active region on the opposite sides of said first gate electrode; and
forming a second source region and a second drain region in said active region on the opposite sides of said second gate electrode.

2. The method as claimed in claim 1, wherein said ion-implanting includes ion-implanting dopants into said active region below said second gate electrode at an oblique angle of incidence in a plane parallel to a gate-width direction of said second gate electrode thereby to form said third doped region.

3. The method as claimed in claim 2, wherein said third doped region is located in a vicinity of at least one of opposite side edges of said active region aligned along the width direction.

4. The method as claimed in claim 2, wherein said ion-implanting of the dopants further includes ion-implanting dopants into said active region at an oblique angle of incidence in a plane parallel to the gate-length direction of said first gate electrode.

5. The method as claimed in claim 1, wherein said first and second gate electrodes include respective protrusions protruding at a side edge of said active region along the width direction, the protrusion of said first gate electrode having a length larger than a length of the protrusion of said second gate electrode.

6. The method as claimed in claim 5, wherein:
the length of the protrusion of said first gate electrode is larger than or equal to 0.3 micrometers;
the length of the protrusion of said second gate electrode is less than or equal to 0.2 micrometers; and
said oblique angle of incidence is set to be in a range from 30 degrees to 60 degrees.

7. The method as claimed in claim 1, wherein said forming of said first source region and said first drain region and said forming of said second source region and said second drain region are performed simultaneously.

8. A semiconductor device, comprising:
a semiconductor substrate in which an isolation structure is formed;
an active region surrounded by said isolation structure in said semiconductor substrate; and
enhancement-mode and depletion-mode FETs formed in and on said active region;
said enhancement-mode FET including:
a first gate electrode formed over a main surface of said semiconductor substrate and crossing over said active region in a width direction of said active region;
first and second doped regions separated from each other, said first and second doped regions being formed below said first gate electrode and formed in said active region on opposite sides of said first gate electrode aligned along a gate-length direction of said first gate electrode; and
a first source region and a first drain region formed in said active region on the opposite sides of said first gate electrode; and
said depletion-mode FET including:
a second gate electrode formed over said main surface and crossing over said active region in a width direction of said active region, said second gate electrode having an overall width along the width direction which is less than an overall width of said first gate electrode;
a third doped region formed below said second gate electrode and continuously formed in said active region so as to extend from one of opposite sides of said second gate electrode to the other along a gate-length direction of said second gate electrode; and
a second source region and a second drain region formed in said active region on the opposite sides of said second gate electrode.

9. The semiconductor device as claimed in claim 8, wherein said third doped region is located in a vicinity of at least one of opposite side edges of said active region aligned along the width direction.

10. The semiconductor device as claimed in claim 8, wherein said first and second gate electrodes include respective protrusions protruding at a side edge of said active region along the width direction, the protrusion of said first gate electrode having a length larger than a length of the protrusion of said second gate electrode.

11. The semiconductor device as claimed in claim 10, wherein:
the length of the protrusion of said first gate electrode is larger than or equal to 0.3 micrometers;
the length of the protrusion of said second gate electrode is less than or equal to 0.2 micrometers; and
said oblique angle of incidence is set to be in a range from 30 degrees to 60 degrees.
